(19) United States
(12) Patent Application Publication
(10) Pub. No.: US 2024/0427697 A1
(43) Pub. Date: Dec. 26, 2024

(54) MEMORY SYSTEM, CONTROL METHOD THEREFOR, AND INFORMATION-PROCESSING DEVICE

(71) Applicant: Kioxia Corporation, Tokyo (JP)

(72) Inventor: Yasufumi KURIHASHI, Yokohama (JP)

(73) Assignee: Kioxia Corporation, Tokyo (JP)

(21) Appl. No.: 18/827,187

(22) Filed: Sep. 6, 2024

Related U.S. Application Data
(63) Continuation of application No. PCT/JP2022/011399, filed on Mar. 14, 2022.

(51) Int. Cl. G06F 12/02

(52) U.S. Cl. CPC G06F 12/0246

(57) ABSTRACT

A memory system includes a nonvolatile memory including memory cells capable of storing user data by a plurality of different storage methods; and a memory controller configured to control the nonvolatile memory. The nonvolatile memory includes a firmware storage area and a user data area, the firmware storage area configured to store firmware and the user data area configured to store user data, and firmware corresponding to each of the storage methods is stored in the firmware storage area. The memory controller uses the firmware corresponding to an externally instructed storage method among the storage methods, thereby controls settings of the nonvolatile memory.

### CROSS-REFERENCE TO RELATED APPLICATION

This application is a continuation of International Application No. PCT/JP2022/011399, filed Mar. 14, 2022, and the entire contents of which are incorporated herein by reference.

### FIELD

An embodiment of the present invention relates to a memory system, a control method therefor, and an information-processing device.

### BACKGROUND ART

A NAND flash memory included in a memory system is becoming increasingly multi-valued.

Recently, there has been increasing demand for changing the data storage quality (such as the reliability or an amount of stored data) according to the characteristics of data which is stored in a NAND flash memory.

### BRIEF DESCRIPTION OF THE DRAWINGS

FIG. 1 is a diagram illustrating an example of a configuration of a memory system according to an embodiment of the present invention.

FIG. 2 is a block diagram illustrating an example of a configuration of a firmware storage area according to a first embodiment.

FIG. 3 is a flowchart illustrating an example of a control method of controlling a memory system according to the first embodiment.

FIG. 4 is a block diagram illustrating an example of a configuration of a firmware storage area according to a second embodiment.

FIG. 5 is a flowchart illustrating an example of a control method of controlling a memory system according to the second embodiment.

### DETAILED DESCRIPTION

A memory system of an embodiment includes: a nonvolatile memory including memory cells capable of storing user data by a plurality of different storage methods; and a memory controller configured to control the nonvolatile memory.

The nonvolatile memory includes a firmware storage area and a user data area, the firmware storage area configured to store firmware and the user data area configured to store user data, and firmware corresponding to each of the storage methods is stored in the firmware storage area. The memory controller uses the firmware corresponding to an externally instructed storage method among the storage methods, thereby controls settings of the nonvolatile memory.

Hereinafter, embodiments of the present invention will be described with reference to the accompanying drawings.

### First Embodiment

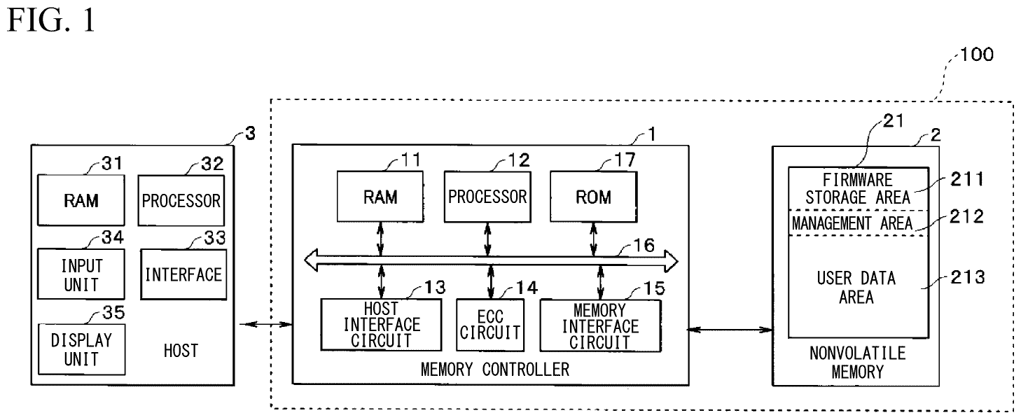

FIG. 1 is a diagram illustrating an example of a configuration of a memory system according to an embodiment of the present invention. FIG. 1 illustrates an information-processing system in which a memory system 100 according to an embodiment is connected to a host 3 which is an information-processing device as an example. The memory system 100 illustrated in FIG. 1 may be, for example, various types of storage devices such as a universal serial bus (USB) memory and a memory card. The memory system 100 is communicatively connected to an external host 3. The host 3 is, for example, an electronic device such as a personal computer or a mobile terminal. For example, when the host 3 is a drive recorder with a camera unit and the memory system 100 is a USB memory, the information-processing system illustrated in FIG. 1 can be used as a system for recording a video captured by the drive recorder in the USB memory.

As illustrated in FIG. 1, the memory system 100 according to this embodiment includes a memory controller 1 and a nonvolatile memory 2. The nonvolatile memory 2 is a memory that stores data in a nonvolatile manner and includes, for example, a NAND flash memory (hereinafter referred to as a NAND memory). The nonvolatile memory 2 includes a memory cell array 21 including a plurality of memory cells and a control circuit (not illustrated). The nonvolatile memory 2 is configured as a NAND memory including memory cells capable of storing data of 3 bits (8 values) for each memory cell, that is, a NAND memory of which a storage method is a triple level cell (TLC) method. The nonvolatile memory 2 can also be configured using a single level cell (SLC) method capable of storing data of 1 bit (two values), a multi-level cell (MLC) method capable of storing data of 2 bits (four values), a quad level cell (QLC) method capable of storing data of 4 bits (16 values), or a method capable of storing data of 5 or more bits. In the following description, “storage method” may be simply referred to as “method.”

The memory controller 1 controls writing of data to the nonvolatile memory 2 according to a writing request from the host 3. The memory controller 1 controls reading of data from the nonvolatile memory 2 according to a reading request from the host 3.

The memory controller 1 includes a random-access memory (RAM) 11, a processor 12, a host interface circuit 13, an error check and correct (ECC) circuit 14, a memory interface circuit 15, and a read-only memory (ROM) 17. The RAM 11, the processor 12, the host interface circuit 13, the ECC circuit 14, the memory interface circuit 15, and the ROM 17 are connected to each other via an internal bus 16.

The host interface circuit 13 outputs a request, user data (writing data), and the like received from the host 3 to the internal bus 16. The host interface circuit 13 transmits user data read from the nonvolatile memory 2, a response from the processor 12, and the like to the host 3.

The memory interface circuit 15 controls a process of writing user data and the like to the nonvolatile memory 2 and a process of reading data from the nonvolatile memory 2 on the basis of an instruction from the processor 12.

The processor 12 comprehensively controls the memory controller 1. The processor 12 is, for example, a central processing unit (CPU) or a micro processing unit (MPU). The processor 12 performs control based on a request received from the host 3 via the host interface circuit 13. For example, the processor 12 instructs the memory interface circuit 15 to write user data and a parity to the nonvolatile memory 2 according to the request from the host 3. The processor 12 instructs the memory interface circuit 15 to read user data and the parity from the nonvolatile memory 2 according to the request from the host 3.

The processor 12 determines a storage area (a memory area) in the nonvolatile memory 2 for user data accumulated in the RAM 11. The user data is stored in the RAM 11 via the internal bus 16. The processor 12 determines a memory area for data in a page unit (page data) which is a writing unit. User data stored in one page (unit data) in the nonvolatile memory 2 is generally encoded by the ECC circuit 14 and stored as a code word in the nonvolatile memory 2. In this embodiment, a code word is not 5 essential. The memory controller 1 may store unit data without encoding the unit data in the nonvolatile memory 2, but a configuration for encoding data into a code word is illustrated as an example in FIG. 1. When the memory controller 1 does not perform encoding, page data is equivalent to unit data. One code word may be generated on the basis of one piece of unit data, or one code word may be generated on the basis of sub data into which unit data is divided. One code word may be generated using a plurality of pieces of unit data.

The processor 12 determines a memory area in the nonvolatile memory 2 which is a writing destination for each unit data piece. Physical addresses are allocated to the memory areas in the nonvolatile memory 2. The processor 12 manages the memory areas which are writing destinations of unit data using the physical addresses. The processor 12 designates the determined memory area (the physical address) and instructs the memory interface circuit 15 to write user data to the nonvolatile memory 2. The processor 12 manages correspondence between a logical address (logical address managed by the host 3) and a physical address for each piece of user data. When a reading request including a logical address is received from the host 3, the processor 12 identifies a physical address corresponding to the logical address, designates the physical address, and instructs the memory interface circuit 15 to read user data.

The ECC circuit 14 encodes user data stored in the RAM 11 and generates a code word. The ECC circuit 14 decodes the code word read from the nonvolatile memory 2.

The RAM 11 temporarily stores user data received from the host 3 until the user data is stored in the nonvolatile memory 2 or temporarily stores data read from the nonvolatile memory 2 until the read data is transmitted to the host 3. The RAM 11 is, for example, a general-purpose memory such as a static random-access memory (SRAM) or a dynamic random-access memory (DRAM).

The ROM 17 stores a booting program. A booting program is a program that is run firstly when the memory system 100 is powered on. The RAM 11 can store the booting program and is used as a work area of the processor 12. That is, when the memory system 100 is powered on, first, the booting program stored in the ROM 17 is loaded to the RAM 11 and is executed by the processor 12. When the booting program is executed, predetermined firmware is read from the nonvolatile memory 2 to the RAM 11. Then, the firmware loaded to the RAM 11 is executed by the processor 12. Through the aforementioned series of operations, the memory controller 1 can perform various operations such as a writing operation and a reading operation.

In the example illustrated in FIG. 1, the memory controller 1 includes the ECC circuit 14 and the memory interface circuit 15. However, the ECC circuit 14 may be incorporated into the memory interface circuit 15. The ECC circuit 14 may be incorporated into the nonvolatile memory 2.

When a writing request is received from the host 3, the memory system 100 operates as follows. The processor 12 temporarily stores data to be written in the RAM 11. The processor 12 reads data stored in the RAM 11 and inputs the read data to the ECC circuit 14. The ECC circuit 14 encodes the input data and inputs a code word to the memory interface circuit 15. The memory interface circuit 15 writes the input code word to the nonvolatile memory 2.

When a reading request is received from the host 3, the memory system 100 operates as follows. The memory interface circuit 15 inputs a code word read from the nonvolatile memory 2 to the ECC circuit 14. The ECC circuit 14 decodes the input code word and stores decoded data in the RAM 11. The processor 12 transmits data stored in the RAM 11 to the host 3 via the host interface circuit 13.

The memory cell array 21 of the nonvolatile memory 2 includes a firmware storage area 211, a management area 212, and a user data area 213. Firmware that is executed by the memory controller 1 in a starting operation after the memory system 100 has been powered on is stored in the firmware storage area 211.

The host 3, which is an information-processing device, reads or writes data with respect to the memory system 100. The host 3 includes a RAM 31, a processor 32, an interface 33, an input unit 34, and a display unit 35.

The processor 32 comprehensively controls the host 3. The processor 32 is, for example, a CPU or an MPU. When a request is received from a user via the input unit 34, the processor 32 performs control based on the request. For example, the processor 32 instructs the interface 33 to write user data to the memory system 100 in response to the request from the user. The processor 32 instructs the interface 33 to read user data from the memory system 100 in response to the request from the user. The processor 32 also instructs the interface 33 to change a storage method in the memory system 100 or to inquire about a storage method in response to the request from the user.

The interface 33 outputs a request input from a user, user data (writing data), or the like to the memory system 100 on the basis of an instruction from the processor 32. The interface 33 causes the display unit 35 to display user data read from the memory system 100 or various types of responses (for example, a storage method).

The input unit 34 receives an instruction from a user and delivers details of the instruction to the processor 32. The input unit 34 includes, for example, a keyboard, a touch panel type display, and a voice input device such as a microphone, which are not illustrated.

The display unit 35 displays user data read from the memory system 100, an inquiry result from a user, and the like on the basis of an instruction from the processor 32.

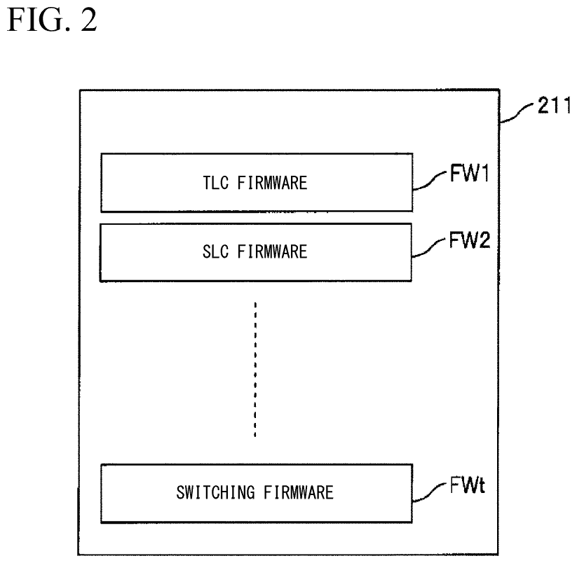

FIG. 2 is a block diagram illustrating an example of a configuration of a firmware storage area according to the first embodiment. A plurality of pieces of firmware are stored in the firmware storage area 211. For example, as illustrated in FIG. 2, three pieces of firmware including TLC firmware FW1, SLC firmware FW2, and switching firmware FWt are stored. The TLC firmware FW1 is firmware that is used when data is stored in the user data area 213 in a TLC method. The SLC firmware FW2 is firmware that is used when data is stored in the user data area 213 in an SLC method. The switching firmware FWt is firmware that is used when the storage method in the user data area 213 is switched. In addition to the aforementioned firmware, firmware that is used when data is stored in the user data area 213 in another method such as an MLC method or a QLC method may be additionally stored in the firmware storage area 211. In response to a request from the memory controller 1, appropriate firmware is selected out of the plurality of pieces of firmware stored in the firmware storage area 211 and is output to the memory controller 1.

Various types of information for controlling the operation of the memory system 100 are stored in the management area 212. The management information is, for example, shift table information (information on an amount of shift at the time of shift reading) and a lookup table (a correspondence table between logical addresses and physical addresses). The management information is copied to the RAM 11 of the memory controller 1 from the nonvolatile memory 2 and is used at the time of powering-on.

Data to be written from the host 3 is stored in the user data area 213. A data storage method in the user data area 213 can be switched according to an instruction from a user. For example, in a normal state, data is stored in the user data area 213 using a TLC method, but the storage method may be switched to an SLC method according to an instruction from a user and data may be stored therein.

A data capacity that can be stored in the nonvolatile memory 2 varies according to a data storage method, and a relationship represented by Expression (1) is satisfied.

$$SLC < MLC < TLC < QLC \qquad Expression ( 1 )$$

That is, the data capacity becomes larger for a storage method in which the number of bits capable of being stored in one memory cell is larger. On the other hand, quality of data stored in the nonvolatile memory 2 satisfies a relationship represented by Expression (2).

$$QLC < TLC < MLC < SLC \qquad Expression ( 2 )$$

The quality of data is exhibited, for example, in a data retention (DR) period. The data retention period is a period in which data written to a certain memory cell is maintained in a state in which the data can be correctly read from the memory cell even when a time elapses after the data has been written. That is, the data retention period for a storage method in which a data capacity capable of being stored is larger becomes shorter, and the data retention period for a storage method in which a data capacity capable of being stored is smaller becomes longer. A user may require a large capacity or may require reliability depending on characteristics of data to be stored. For example, when the host 3 is a drive recorder with a camera unit, imaging data corresponding to a long time is normally intended to be stored, and thus a large capacity is required for the nonvolatile memory 2. On the other hand, when an accident occurs or the like, imaging data is intended to be reliably stored for a long time, and thus high reliability (long data retention period) is required for the nonvolatile memory 2. That is, by employing the memory system 100 in which the data storage method can be changed as in this embodiment, data can be normally written using a method with a large data capacity capable of being stored such as a TLC method, and the storage method can be changed to a method with a longer data retention period such as an SLC method and data can be written in a situation in which high reliability is required. Accordingly, the user does not have to switch and use memory systems 100 with different storage methods according to data characteristics, which enhances convenience.

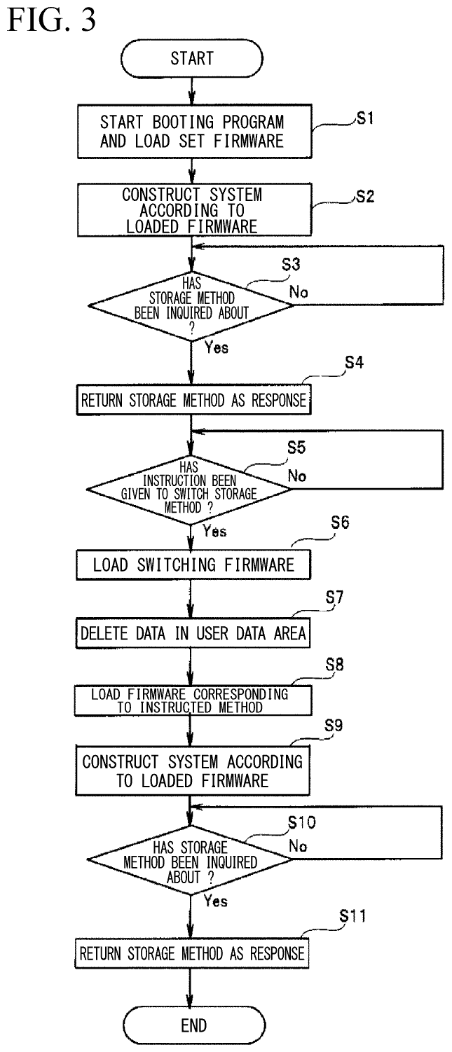

A data storage method switching method in the memory system according to this embodiment will be described below. FIG. 3 is a flowchart illustrating an example of a control method of controlling the memory system according to the first embodiment. First, when the memory system 100 is powered on, the memory controller 1 starts a booting program stored in the ROM 17 and reads firmware corresponding to a set method from the nonvolatile memory 2 (Step (hereinafter abbreviated to S) 1).

When the memory system 100 has not been used and is powered on for the first time, firmware (for example, TLC firmware FW1) corresponding to a method set in advance for the memory system 100 is read. When the memory system 100 has been used already and is powered on for the second or later time, firmware corresponding to a method set before the memory system 100 has been finally powered off is read. For example, when data is being written in the SLC method before the memory system 100 is finally powered off, the SLC firmware FW2 is read. For example, when data is being written in the TLC method before the memory system 100 is finally powered off, the TLC firmware FW1 is read.

When firmware is loaded to the memory controller 1, the firmware is executed by the processor 12 and a system is constructed (S2). That is, various operations including a data writing operation and a data reading operation with respect to the nonvolatile memory 2 can be performed in a method supported by the firmware. When S2 is completed, the host 3 can write or read data with respect to the memory system 100.

A user can inquiry about (ascertain) a current storage method in the memory system 100 via the host 3 while using the memory system 100. When an inquiry about the storage method in the memory system 100 has been received from the host 3 (S3: YES), the memory controller 1 returns the current storage method as a response (S4). When an inquiry about the storage method in the memory system 100 has not been received from the host 3 (S3: NO), the memory system 100 is continuously used in the current storage method.

When a user has instructed to switch to a storage method other than the current storage method after the current storage method has been returned as a response (S5: YES), the memory controller 1 reads switching firmware FWt from the nonvolatile memory 2 (S6). The switching firmware FWt is executed by the processor 12, and all data stored in the user data area 213 is deleted (S7). Then, firmware corresponding to the storage method designated by the user in S5 is read to the memory controller 1 (S8). For example, when it has been instructed to switch to the SLC method in S5, the SLC firmware FW2 is read in S8.

When firmware is loaded to the memory controller 1, the firmware is executed by the processor 12 and a system is constructed (S9). That is, various operations including a data writing operation and a data reading operation with respect to the nonvolatile memory 2 can be performed using a storage method supported by the firmware. When S9 is completed, a user can write or read data with respect to the memory system 100 using the instructed storage method. In S9, it is preferable that a response signal indicating switching completion be output from the memory system 100 to the host 3 after construction of a system has been completed.

When an inquiry about the storage method in the memory system 100 has been received from the host 3 after the storage method has been switched (S10: YES), the memory controller 1 returns the current storage method (the switched storage method) as a response (S11). When an inquiry about the storage method in the memory system 100 has not been received from the host 3 (S10: NO), the memory system 100 is continuously used in the current storage method (the switched storage method).

In this way, the memory system 100 according to this embodiment includes a plurality of pieces of firmware, and the pieces of firmware correspond to storage methods in which the number of bits of data stored in one memory cell varies. The memory system 100 also includes the switching firmware FWt for performing a system reconstructing operation accompanying switching of the storage method. Accordingly, a user can use the memory system 100 with switching to a desired storage method, which enhances convenience.

### Second Embodiment

In the first embodiment, the memory system 100 includes a plurality of pieces of firmware, and firmware is prepared for each data storage method. On the other hand, the second embodiment is different therefrom, in that the memory system 100 includes only one piece of firmware. The configuration of the memory system 100 according to this embodiment is the same as that in the first embodiment illustrated in FIG. 1 except for the configuration of the firmware storage area 211. The configuration of the firmware storage area 211 different from that in the first embodiment will be described below.

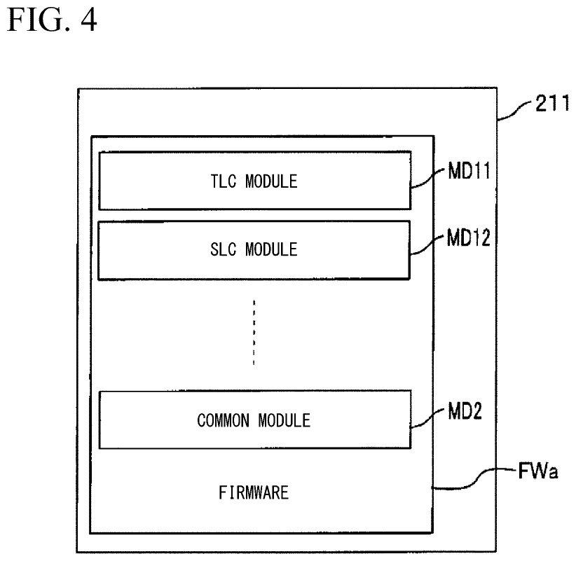

FIG. 4 is a block diagram illustrating an example of a configuration of the firmware storage area according to the second embodiment. One piece of firmware FWa is stored in the firmware storage area 211. The firmware FWa includes a plurality of modules. The firmware FWa includes, for example, three modules including a TLC module MD11, an SLC module MD12, and a common module MD2 as illustrated in FIG. 4. For example, for processes in which operations are different according to the storage method such as setting a reading voltage in a reading operation and setting a program loop in a writing operation, processes corresponding to the storage methods are stored in the TLC module MD11 and the SLC module MD12. A common process regardless of the storage methods such as a wear leveling operation is stored in the common module MD2.

The firmware FWa may further include a module that is used when data is stored in the user data area 213 using another storage method such as an MLC module or a QLC module in addition to the aforementioned modules.

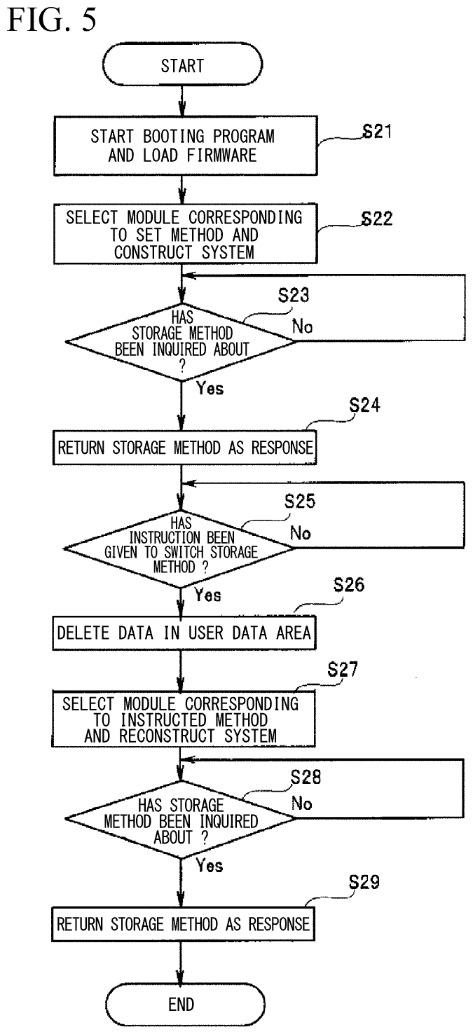

A storage method switching method in the memory system according to this embodiment will be described below. FIG. 5 is a flowchart illustrating an example of a control method of controlling the memory system according to the second embodiment. First, when the memory system 100 is powered on, the memory controller 1 starts a booting program stored in the ROM 17 and reads the firmware FWa from the nonvolatile memory 2 and stores the read firmware FWa in the RAM 11 (S21).

When the firmware FWa is loaded to the memory controller 1, a module corresponding to the set storage method and the common module are selected from the firmware FWa and are executed by the processor 12 (S22). When the memory system 100 has not been used and is powered on for the first time, a module (a TLC module MD11) corresponding to a storage method (for example, a TLC method) set in advance for the memory system 100 and the common module MD2 are selected. When the memory system 100 has been used already and is powered on for the second or later time, a module corresponding to a storage method set before the memory system 100 has been finally powered off and the common module are selected. For example, when data is being written in the SLC method before the memory system 100 is finally powered off, the SLC module MD12 and the common module MD2 are selected. That is, various operations including a data writing operation and a data reading operation with respect to the nonvolatile memory 2 can be performed using the storage method supported by the selected modules. When S22 is completed, the host 3 can write or read data with respect to the memory system 100.

A user can inquire about (ascertain) a current storage method in the memory system 100 via the host 3 while using the memory system 100. When an inquiry about the storage method in the memory system 100 has been received from the host 3 (S23: YES), the memory controller 1 returns the current storage method as a response (S24). When an inquiry about the storage method in the memory system 100 has not been received from the host 3 (S23: NO), the memory system 100 is continuously used in the current storage method.

When a user has instructed to switch to a storage method other than the current storage method after the current storage method has been returned as a response (S25: YES), all data stored in the user data area 213 is deleted (S26). The memory controller 1 selects a module corresponding to the designated storage method and the common module from the firmware FWa stored in the RAM 11 and reconstructs a system (S27). For example, when the storage method is switched from the TLC method to the SLC method, the TLC module MD11 is switched to a non-selected state from a state in which the TLC module MD11 and the common module MD2 are selected, selects the SLC module MD12 and the common module MD2, and reconstructs the system. This reconstruction may accompany restarting of the memory system 100 or may be performed by only switching a selected module.

When S27 is completed, various operations including a data writing operation and a data reading operation with respect to the nonvolatile memory 2 can be performed using a storage method supported by the selected modules. That is, a user can write or read data with respect to the memory system 100 using the instructed storage method. In S27, it is preferable that a response signal indicating switching completion be output from the memory system 100 to the host 3 after construction of the system has been completed.

When an inquiry about the storage method in the memory system 100 has been received from the host 3 after the storage method has been switched (S28: YES), the memory controller 1 returns the current storage method (the switched storage method) as a response (S29). When an inquiry about the storage method in the memory system 100 has not been received from the host 3 (S28: NO), the memory system 100 is continuously used in the current storage method (the switched storage method).

In this way, the memory system 100 according to this embodiment includes one piece of firmware FWa including a plurality of modules, and the firmware FWa includes modules for performing different processes according to storage methods and a module corresponding to a common process regardless of the storage methods. As the modules for performing different processes according to the storage methods, a module corresponding to each storage method is provided. When the storage method is switched, a necessary module is selected from the firmware FWa read by the memory controller 1 and a system is reconstructed. Accordingly, since firmware does not have to be newly loaded from the nonvolatile memory 2 at the time of switching the storage method, it is possible to shorten a switching time and thus to further enhance convenience for a user.

In the aforementioned embodiments, the TLC method is described as the storage method set in advance in the memory system 100, but the present invention is not limited thereto, and an MLC method, a QLC method, or a storage method in which the number of bits of data stored in one memory cell is equal to or greater than 5 values may be employed. The storage method which is a switching destination is not limited to the SLC method, and an MLC method, a QLC method, or a storage method in which the number of bits of data stored in one memory cell is equal to or greater than 5 values may be employed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory including memory cells capable of storing user data by a plurality of different storage methods; and
a memory controller configured to control the nonvolatile memory,
wherein the nonvolatile memory includes a firmware storage area and a user data area, the firmware storage area configured to store firmware and the user data area configured to store user data, and firmware corresponding to each of the storage methods is stored in the firmware storage area, and
wherein the memory controller uses the firmware corresponding to an externally instructed storage method among the storage methods, thereby controls settings of the nonvolatile memory.

2. The memory system according to claim 1, wherein a plurality of pieces of firmware are stored in the firmware storage area, and the pieces of firmware correspond to the different storage methods.

3. The memory system according to claim 2, wherein switching firmware configured to switch the storage methods of the nonvolatile memory is further stored in the firmware storage area.

4. The memory system according to claim 3, wherein the memory controller loads and executes the firmware corresponding to the instructed storage method after loading and executing the switching firmware in switching to the instructed storage method.

5. The memory system according to claim 4, wherein data stored in the user data area is deleted by executing the switching firmware.

6. The memory system according to claim 1, wherein one piece of firmware is stored in the firmware storage area, the one piece of firmware includes a plurality of individual modules and a common module,
the individual modules is configured to perform a process corresponding to each of the plurality of different storage methods, and
the common module is configured to perform a common process regardless of the storage methods.

7. The memory system according to claim 6, wherein the memory controller selects and executes the individual module corresponding to the instructed storage method and the common module after data stored in the user data area has been deleted in switching to the instructed storage method.

8. A control method of controlling a memory system, the memory system comprising a nonvolatile memory including memory cells capable of storing user data by a plurality of different storage methods, the control method comprising:
loading firmware corresponding to a first storage method from the nonvolatile memory and executing the loaded firmware; and
loading and executing firmware corresponding to a second storage method different from the first storage method after deleting data in an area storing user data in the nonvolatile memory when an instruction to switch to the second storage method is received.

9. A control method of controlling a memory system, the memory system comprising a nonvolatile memory including memory cells capable of storing user data by a plurality of different storage methods, the control method comprising:
loading firmware from the nonvolatile memory and selecting and executing a module corresponding to a first storage method included in the loaded firmware; and
selecting a module corresponding to a second storage method different from the first storage method from the firmware and executing the selected module after deleting date in an area storing user data in the nonvolatile memory when an instruction to switch to the second storage method is received.

10. An information-processing device capable of reading and writing user data from and to a memory system, wherein
the memory system including:
a nonvolatile memory including memory cells capable of storing user data by a plurality of different storage methods; and
a memory controller configured to control the nonvolatile memory,
the information-processing device comprising:
an input unit configured to set a storage method of the user data in the nonvolatile memory to a second storage method different from a first storage method which has been set;
a processor configured to instruct the memory controller to switch to the second storage method; and
an interface configured to transmit an instruction from the processor to the memory controller and to receive a response from the memory controller.
